(19) United States
(12) Patent Application Publication
(10) Pub. No.: US 2012/0224340 A1
(43) Pub. Date: Sep. 6, 2012

(54) ELECTRONIC DEVICE WITH MOUNTING BRACKET FOR RECEIVING EXPANSION CARD AND CONNECTOR

(75) Inventors: CHAO GENG, Wuhan City (CN); BIAO ZENG, Wuhan City (CN); QIU-HUA BIN, Wuhan City (CN); ZHI-GUO ZHANG, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/369,532

(22) Filed: Feb. 9, 2012

(30) Foreign Application Priority Data
Mar. 2, 2011 (CN) 201110049894.X

(51) Int. Cl. H05K 7/14

(52) U.S. Cl. 361/759

(57) ABSTRACT

An electronic device includes a sidewall, a mounting bracket, an expansion card, and a connector. The mounting bracket is mounted to the sidewall. The mounting bracket includes a cover portion, a plurality of retaining members located on the cover portion, and a guiding channel defined between two adjacent retaining members of the plurality of retaining members. The expansion card includes a mounting tab located in the guiding channel. The connector is mounted on one of the plurality of the retaining members and is removable for connecting to the expansion card.

### BACKGROUND

1. Technical Field

The present disclosure relates to electronic devices, especially to an electronic device with a mounting bracket for receiving expansion cards and connectors to the expansion card.

2. Description of Related Art

Expansion cards can be inserted into an expansion slot of a computer motherboard or backplane to add functionality to a computer system via the expansion bus. Some expansion cards also need to be connected to a power supply of the computer system. However, the power supply cables for the expansion cards may interfere with other working hardware in the computer.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an enclosure in one embodiment.

FIG. 2 is an enlarged view of a connector of the enclosure of FIG. 1.

FIG. 3 is an exploded, isometric view of the enclosure of FIG. 1 but viewed from another aspect.

FIG. 4 is an enlarged view of a connector of the enclosure of FIG. 3.

FIG. 5 is a partially assembled view of the enclosure of FIG. 1.

FIG. 6 is an assembled view of the enclosure of FIG. 1.

FIG. 7 is an enlarged view of an encircled portion VII of the electronic device of FIG. 6.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

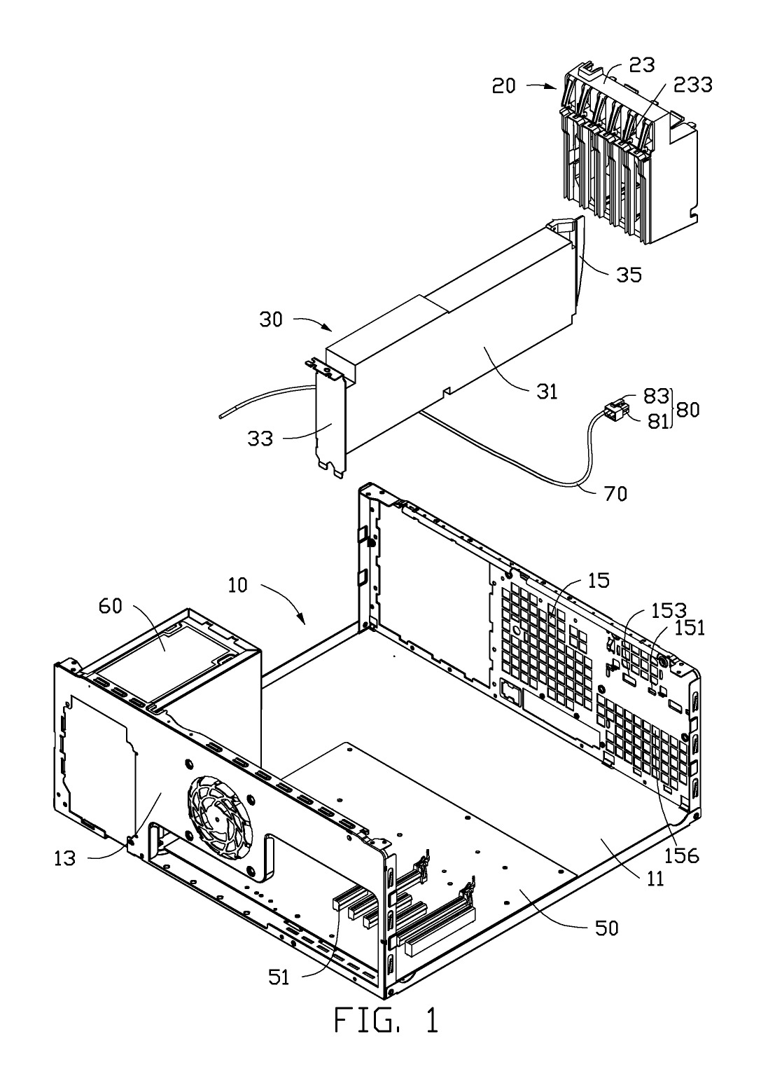

Referring to FIG. 1 through FIG. 3, in one embodiment, an electronic device includes a chassis 10, a power supply 60 mounted to the chassis 10, a cable 70, a connector 80 connected to the power supply 60 through the cable 70, a motherboard 50, a mounting bracket 20, and an expansion card 30.

The chassis 10 includes a bottom wall 11, a first sidewall 13, and a second sidewall 15. The first sidewall 13 and the second sidewall 15 are located on opposite sides of the bottom wall 11. The first sidewall 13 and the second sidewall 15 are substantially perpendicular to the bottom wall 11. The second sidewall 15 defines a plurality of vents 156, at least one locking hole 153, and at least one positioning hole 151.

A plurality of slots 51 is located on the motherboard 50.

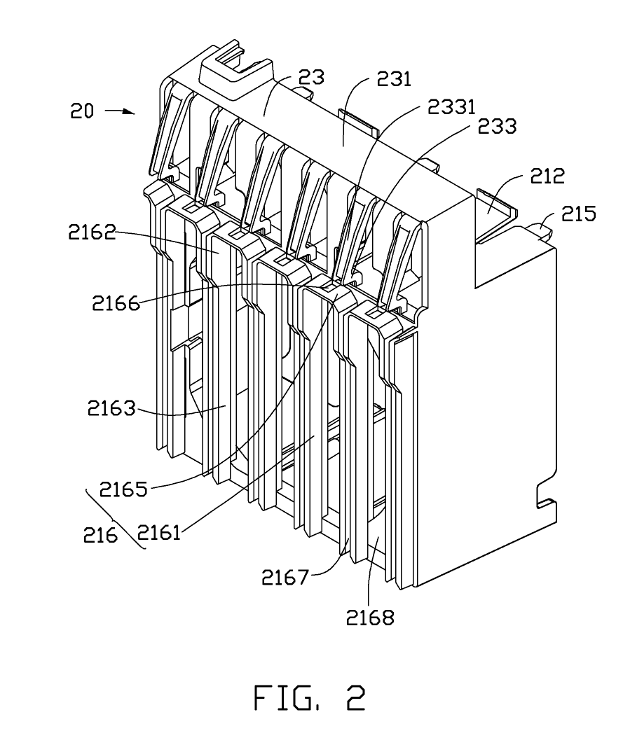

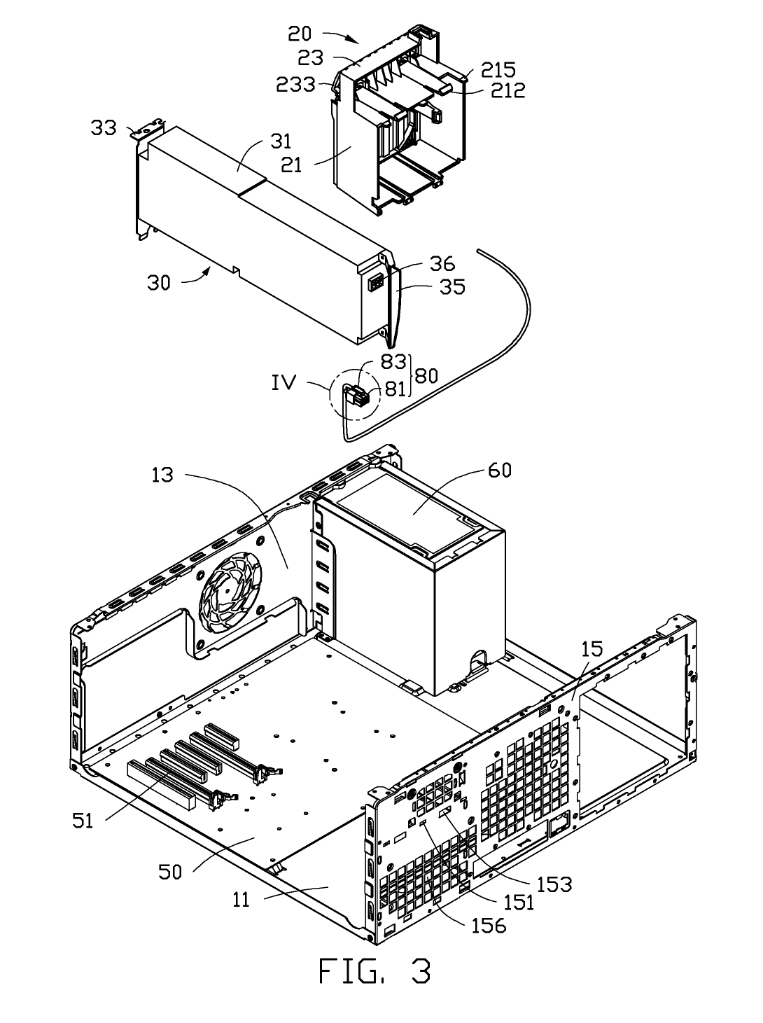

Referring to FIG. 2, the mounting bracket 20 includes a cover portion 21 (shown in FIG. 3), a plurality of retaining members 216, and a top portion 23 located on top of the cover portion 21. A receiving space is defined in the cover portion 21 for receiving a fan (not shown).

The cover portion 21 includes at least one resilient hook 212 and at least one positioning tab 215. The plurality of retaining members 216 is located on a side of the cover portion 21. Each retaining member 216 is U-shaped. Each of the plurality of retaining members 216 includes a retaining wall 2165 and two substantially parallel locating walls 2161 substantially perpendicular to the retaining wall 2165. A retaining hole 2166 is defined in the retaining wall 2165 of each of the plurality of retaining members 216. Each of the locating walls 2161 includes a wide portion 2162 and a narrow portion 2163. A passageway 2168 is defined between the two locating walls 2161 of each of the plurality of retaining members 216. A guiding channel 2167 is defined between the two locating walls 2161 of two adjacent retaining members 216 of the plurality of retaining members 216.

The top portion 23 includes a top wall 231 and a plurality of guiding members 233 oblique to the top wall 231. Each of the plurality of guiding members 233 extends toward each guiding channel 2167 and defines a guiding slot 2331 along an extending direction of each of the plurality of the guiding member 233 for guiding the expansion card 30.

The expansion card 30 includes a body 31, a connector interface 36, a block tab 33, and a mounting tab 35. The block tab 33 and mounting tab 35 are located on opposite sides of the body 31. The connector interface 36 is located on the body 31.

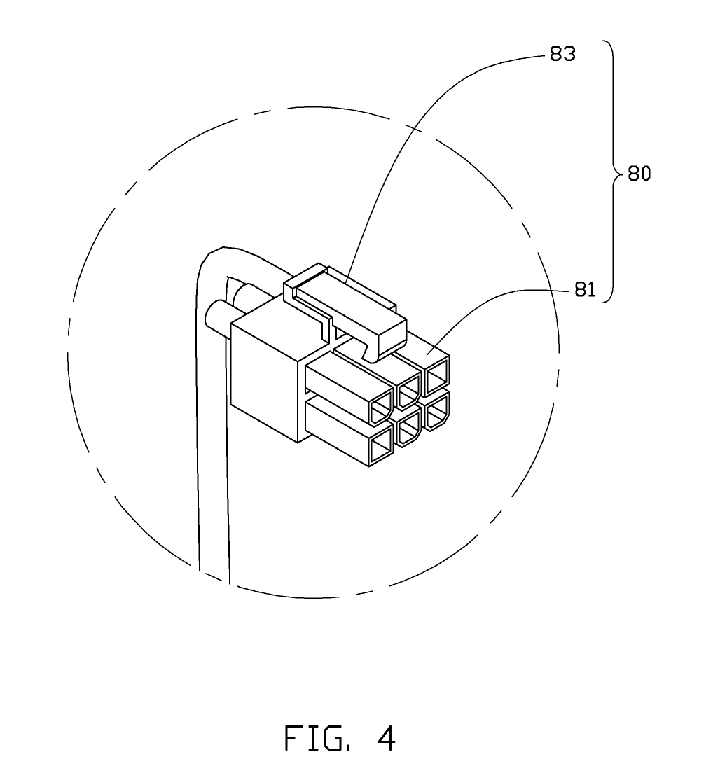

Referring to FIG. 4, the connector 80 includes a head 81 and a resilient locking portion 83 corresponding to the retaining hole 2166.

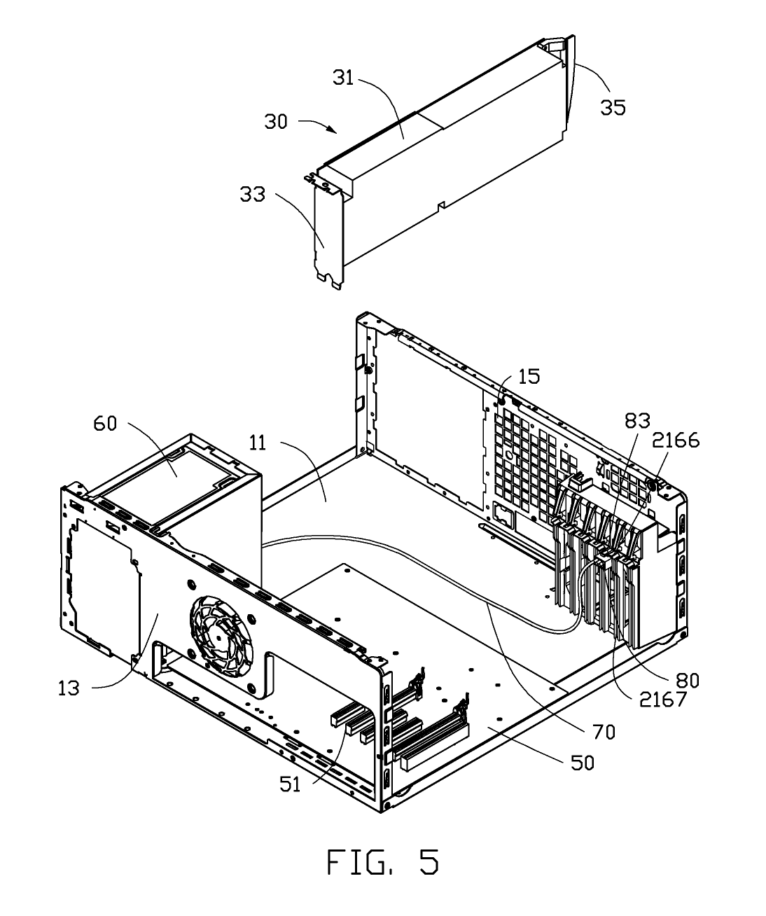

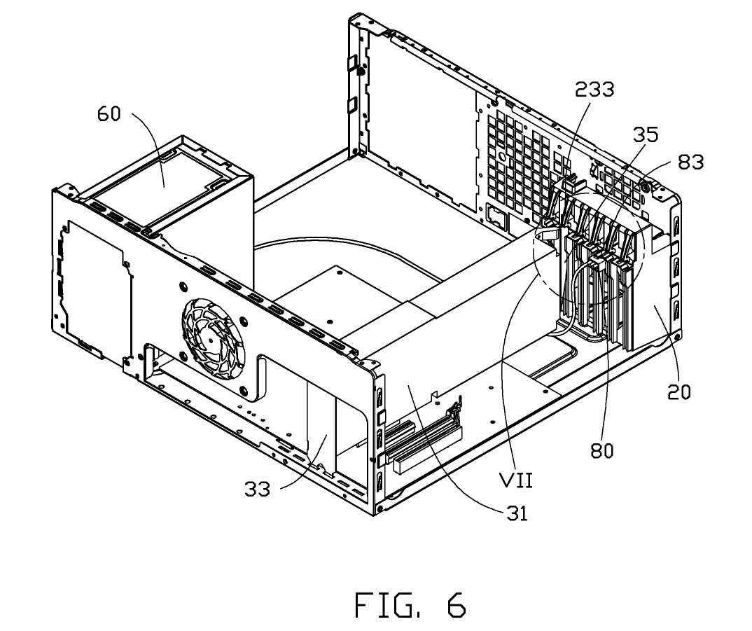

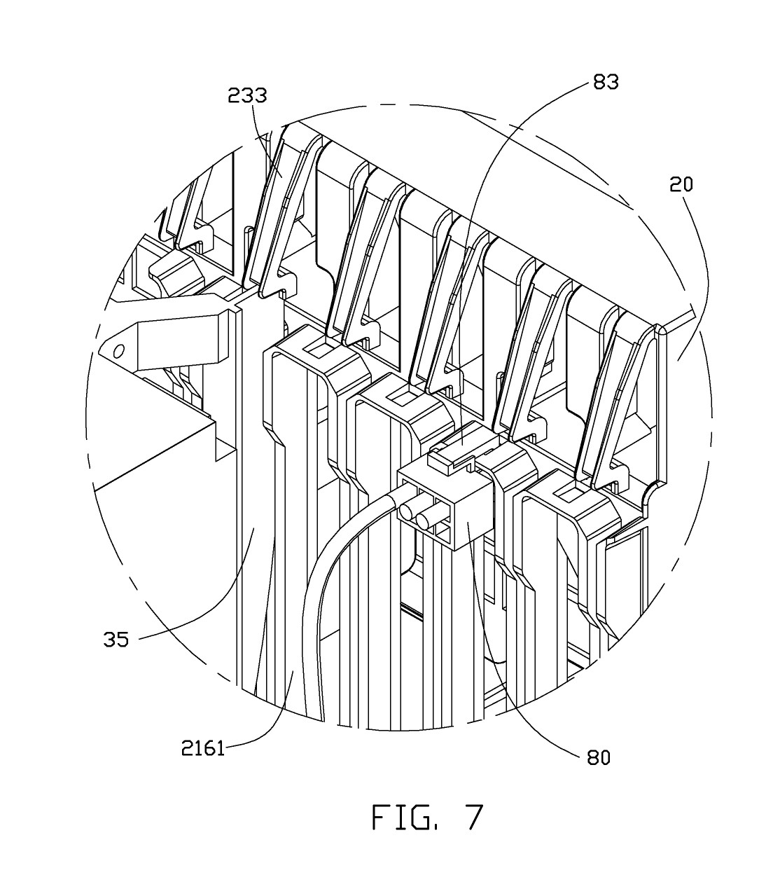

Referring to FIG. 5 through FIG. 7, in assembly, the mounting bracket 20 is mounted to the second sidewall 15. The at least one resilient hook 212 is engaged with the at least one locking hole 153. The at least one positioning tab 215 extends into the positioning hole 151 to prevent the mounting bracket 20 from further movement relative to the second sidewall 15. The motherboard 50 is located on the bottom wall 11 of the chassis 10.

Before installing the expansion card 30, the connector 80 can be mounted to the retaining wall 2165 of one retaining member 216 with the resilient locking portion 83 engaging with the retaining hole 2166 of the retaining member 216.

When the expansion card 30 is mounted to the slot 51 of motherboard 50, the mounting tab 35 can slide along the guiding slot 2331 of the guiding member 233 and slide into the guiding channel 2167. The block tab 33 is mounted to the first sidewall 13. The connector 80 can be removed from the retaining member 216 and is mounted to the expansion card 30 for providing power to the expansion card 30. The receiving space may communicate with the vent 156 and the passageway 2168 of the retaining member 216 for dissipating heat from the expansion card 30 and other heat generating elements inside the chassis 10.

In other embodiments, the guiding member 233 may be resiliently deformed when guiding the mounting tab 35 into the guiding channel 2167 and can block the mounting tab 35 from moving out of the bracket 20 when the expansion card 30 is mounted in the chassis 10.

It is also to be understood, however, that even though numerous characteristics and advantages have been set forth in the foregoing description of the embodiments, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An electronic device, comprising:
a sidewall defining a vent;
a mounting bracket mounted to the sidewall, the mounting bracket comprising a cover portion, a plurality of retaining members located on a side of the cover portion, and a receiving space defined in the cover portion communicating with the vent, each of the plurality of retaining members comprising a retaining wall, two substantially parallel locating walls, and a passageway defined between the two locating walls, the passageway communicating with the receiving space; and
a connector mounted on the retaining wall of one of the plurality of the retaining members, and located between the two locating walls of the one of the plurality of the retaining members.

2. The electronic device of claim 1, wherein the mounting bracket further comprises a plurality of guiding channels, and each of the guiding channels is defined between every two locating walls of two adjacent retaining members of the plurality of retaining members.

3. The electronic device of claim 2, wherein the mounting bracket further comprises a top portion located on top of the cover portion, the top portion comprises a top wall and a plurality of guiding members oblique to the top wall, and each of the plurality of guiding members extends toward each guiding channel.

4. The electronic device of claim 3, wherein the each of the plurality of guiding members defines a guiding slot substantially along an extending direction of the each of the plurality of the guiding members.

5. The electronic device of claim 2, further comprising an expansion card, wherein the expansion card comprises a mounting tab located in each of the guiding channels.

6. The electronic device of claim 5, further comprising a power supply, wherein the connector is connected to the power supply and is adapted to provide power to the expansion card.

7. The electronic device of claim 1, wherein the each of the plurality of retaining members is U-shaped.

8. The electronic device of claim 1, wherein the retaining wall of the each of the plurality of retaining members defines a retaining hole, and the connector comprises a resilient locking portion engaged in a corresponding retaining hole.

9. The electronic device of claim 1, wherein each of the locating walls of the plurality of the retaining members comprises a wide portion and a narrow portion, and the connector is located between the two wide portions of the one of the retaining members.

10. An electronic device, comprising:
a sidewall;
a mounting bracket mounted to the sidewall, the mounting bracket comprising a cover portion, a plurality of retaining members located on a side of the cover portion, and a guiding channel, each of the plurality of retaining members comprising two substantially parallel locating walls, and the guiding channel being defined between two locating walls of two adjacent retaining members of the plurality of retaining members;
an expansion card, the expansion card comprising a mounting tab located in the guiding channel; and
a connector mounted on one of the plurality of the retaining members, and located between the two locating walls of the one of the plurality of the retaining members.

11. The electronic device of claim 10, wherein the sidewall defines a vent, and a receiving space is defined in the cover portion communicating with the vent.

12. The electronic device of claim 11, wherein a passageway is defined between the two locating walls, and the passageway communicates with the receiving space.

13. The electronic device of claim 10, wherein the mounting bracket further comprises a top portion located on top of the cover portion, the top portion comprises a top wall and a plurality of guiding members oblique to the top wall, and each of the plurality of guiding members extends toward each guiding channel.

14. The electronic device of claim 13, wherein the each of the plurality of guiding members defines a guiding slot substantially along an extending direction of the each of the plurality of the guiding members.

15. The electronic device of claim 10, further comprising a power supply, wherein the connector is connected to the power supply and is adapted to provide power to the expansion card.

16. The electronic device of claim 10, wherein the each of the retaining members is U-shaped.

17. The electronic device of claim 10, wherein the each of the plurality of retaining members further comprises a retaining wall, and the connector is mounted to the retaining wall of one of the plurality of retaining members.

18. The electronic device of claim 17, wherein the retaining wall of the each of the plurality of retaining members defines a retaining hole, and the connector comprises a resilient locking portion engaged in a corresponding retaining hole.

19. The electronic device of claim 10, wherein each of the locating walls of the plurality of the retaining members comprises a wide portion and a narrow portion, and the connector is located between the two wide portions of the one of the retaining members.

20. An electronic device, comprising:
a sidewall;
a mounting bracket mounted to the sidewall, the mounting bracket comprising a cover portion, a plurality of retaining members located on the cover portion, and a guiding channel defined between two adjacent retaining members of the plurality of retaining members;
an expansion card, the expansion card comprising a mounting tab located in the guiding channel; and
a connector mounted on one of the plurality of the retaining members and being removable for connecting to the expansion card.
